(19) United States
(12) Patent Application Publication
(10) Pub. No.: US 2026/0020179 A1
(43) Pub. Date: Jan. 15, 2026

(54) Server System Storage System Storage Module Thermal Pad Alignment System

(71) Applicant: Dell Products L.P., Round Rock, TX (US)

(72) Inventors: Yen-Hsing Lin, Datong District (TW); Chih-Sheng Chou, Xizhi District (TW); Ying-Hsien Tseng, Taipei (TW)

(21) Appl. No.: 18/772,488

(22) Filed: Jul. 15, 2024

(51) Int. Cl. H05K 7/14; H05K 7/20

(52) U.S. Cl. CPC H05K 7/1487; H05K 7/20445; H05K 7/20709

(57) ABSTRACT

A bottom system of storage system. The bottom system includes a bottom component; and a storage module thermal pad alignment system for attaching to the bottom component, the storage module thermal pad alignment system including an alignment component, the alignment component comprising an alignment panel, the alignment panel including an outside wall and an inside wall; and, a thermal pad, the thermal pad being affixed to the inside wall of the alignment panel in a preconfigured position, the alignment panel and the thermal pad being configured as a single part.

### BACKGROUND OF THE INVENTION

### Field of the Invention

The present invention relates to information handling systems. More specifically, embodiments of the invention relate to server type information handling systems within information technology (IT) environments.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

It is known to use information handling systems and related IT systems within information technology (IT) environments such as data centers.

### SUMMARY OF THE INVENTION

A system and method for providing a storage system with a storage module thermal pad alignment system via which a thermal pad can be toollessly installed into a storage component of the storage system.

In one embodiment, the invention relates to an alignment component of a storage module thermal pad alignment system for use with a storage system for an information handling system, comprising: an alignment panel, the alignment panel including an outside wall and an inside wall; and, a thermal pad, the thermal pad being affixed to the inside wall of the alignment panel in a preconfigured position, the alignment panel and the thermal pad being configured as a single part.

In another embodiment, the invention relates to a bottom system of a storage system comprising: a bottom component; a storage card, the storage card being configured to be mounted within the bottom component; and, a storage module thermal pad alignment system for attaching to the bottom component, the storage module thermal pad alignment system comprising an alignment component, the alignment component comprising an alignment panel, the alignment panel including an outside wall and an inside wall; and, a thermal pad, the thermal pad being affixed to the inside wall of the alignment panel in a preconfigured position, the alignment panel and the thermal pad being configured as a single part.

In another embodiment, the invention relates to a system comprising: a chassis; a processor contained within the chassis; a data bus coupled to the processor; and, a storage system comprising a bottom system, the bottom system comprising a bottom component; a storage card, the storage card being configured to be mounted within the bottom component; and, a storage module thermal pad alignment system for attaching to the bottom component, the storage module thermal pad alignment system comprising an alignment component, the alignment component comprising an alignment panel, the alignment panel including an outside wall and an inside wall; and, a thermal pad, the thermal pad being affixed to the inside wall of the alignment panel in a preconfigured position, the alignment panel and the thermal pad being configured as a single part.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 shows a general illustration of components of an information handling system as implemented in the system and method of the present invention.

FIG. 2 shows a perspective view of a portion of a data center within an IT environment.

FIG. 3 shows a generalized perspective view of an example server type information handling system.

FIG. 4 shows a storage system with a plurality of storage cartridges.

FIG. 5 shows a perspective view of a storage cartridge of a storage system.

FIGS. 6A, 6B and 6C, generally referred to as FIG. 6, show a plurality of views of a bottom storage component bottom system.

FIGS. 7A, 7B and 7C, generally referred to as FIG. 7, show a plurality of views of a storage module thermal pad alignment system.

### DETAILED DESCRIPTION

Various aspects of the disclosure include an appreciation that it is known to provide information handling systems with storage systems such as boot optimized storage systems. Various aspects of the disclosure include an appreciation that it is known to storage systems, such as boot optimized storage systems, which are hot swappable. Various aspects of the present disclosure include an appreciation that it is known to provide storage systems which can mount a plurality of storage components. Various aspects of the present disclosure include an appreciation that each of the plurality of storage components can include one or more storage devices. Various aspects of the present disclosure include an appreciation that the one or more storage devices often conform to particular storage device specifications. Various aspects of the present disclosure include an appreciation that one such storage device specification is the M.2 storage device specification. Various aspects of the present disclosure include an appreciation that storage device specification often defines particular dimensions for cards, such as internal memory cards, for the cards to conform to the storage device specification. Various aspects of the present disclosure include an appreciation the particular dimensions defined by a storage device specification can include areas defined as keep out zones.

Various aspects of the present disclosure include an appreciation that certain known storage components use a thermal pad when a card is mounted within the storage component. Various aspects of the present disclosure include an appreciation that the card is often adhered to a portion of the storage component via the thermal pad. Various aspects of the present disclosure include an appreciation that it can be necessary to remove a card from the storage component, such as when there is some sort of repair needed for the storage component or when the card is upgraded. Various aspects of the present disclosure include an appreciation that it can be challenging to accurately install a thermal pad within the storage component.

Various aspects of the present disclosure include an appreciation that it may be desirable for an end user to upgrade a storage card such as a boot optimized storage system (BOSS) card. Various aspects of the present disclosure include an appreciation that modifications to the storage card can necessitate accessing and modifying a storage card carrier module. Various aspects of the present disclosure include an appreciation that accessing and modifying the storage card module can require rework a thermal pad which is positioned on a top cage of the storage card carrier module. Various aspects of the present disclosure include an appreciation that proper positioning of the thermal pad is important to the thermal performance of the storage module.

Various aspects of the present disclosure include an appreciation that storage module thermal pads are often protected via a liner, which is removed to adhere the storage module thermal pad. Various aspects of the present disclosure include an appreciation that because the thermal pad is often very soft and elastically, it can be difficult for end users to rework the thermal pad when reassembling the storage module. Various aspects of the present disclosure include an appreciation that end users are sometime provided with specific fixtures to facilitate the thermal pad rework process. Accordingly, various aspects of the present disclosure include an appreciation that it would be desirable to provide a storage system with a storage system thermal pad alignment system via which thermal pads of a storage component can be reworked.

A system and method are disclosed for providing a storage system with a storage module thermal pad alignment system via which a thermal pad can be toollessly installed into a storage component of the storage system. In certain embodiments, the storage module thermal pad alignment system includes an alignment component. In certain embodiments, the alignment component is configured from a rigid material. In certain embodiments, the rigid material includes mylar. In certain embodiments, the one side of the thermal pad is adhered to the alignment component. In certain embodiments, the alignment component enhances the rigidness of the storage module thermal pad alignment system during operation. In certain embodiments, the thermal pad alignment system includes alignment indicia to indicate a position to which the thermal pad should be affixed. Such a storage module thermal pad alignment system enables a user to rework a storage component without the need for specific fixtures to facilitate the thermal pad rework process.

In certain embodiments, the alignment component includes additional alignment features which can be used with reworking a storage component. In certain embodiments, the additional alignment features facilitate positioning the thermal pad alignment system when reassembling the storage module thermal pad alignment system to a bottom component of a storage module.

In certain embodiments, the storage system comprises a boot optimized storage system. In certain embodiments, the boot optimized storage system comprises a redundant array of independent disks (RAID) solution optimized for booting an operating system of a server. In certain embodiments, the boot optimized storage system comprises a plurality of serial advanced technology advancement (SATA) solid state devices (SSDs), a host interface (such as a PCIe host interface), a device interface (such as a SATA device interface), or a combination thereof. In certain embodiments, the solid state devices are included within a storage card. In certain embodiments, the storage card corresponds to an M.2 type storage card. In certain embodiments, the storage card corresponds to a boot optimized storage system M.2 type storage card.

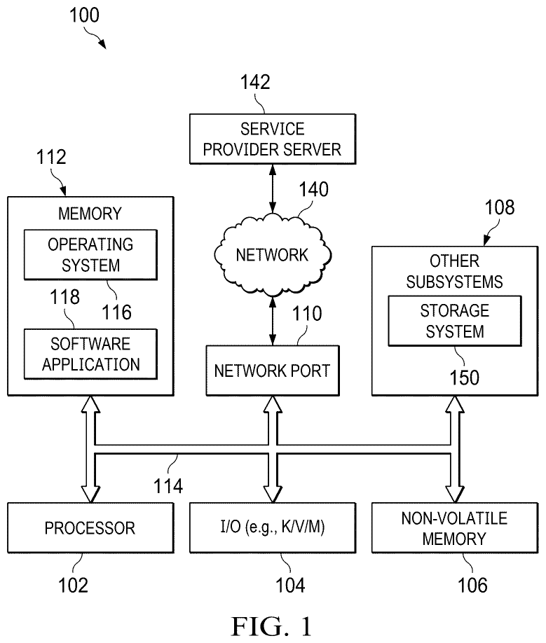

FIG. 1 shows a generalized illustration of an information handling system 100 that can be used to implement the system and method of the present invention. The information handling system 100 includes a processor (e.g., central processor unit or “CPU”) 102, input/output (I/O) devices 104, such as a display, a keyboard, a mouse, and associated controllers, a hard drive or disk storage 106, and various other subsystems 108. In various embodiments, the information handling system 100 also includes network port 110 operable to connect to a network 140, which is likewise accessible by a service provider server 142. In various embodiments, one or both the other subsystems 108 or the network port 110 include storage system 150. The information handling system 100 likewise includes system memory 112, which is interconnected to the foregoing via one or more buses 114. System memory 112 further comprises operating system (OS) 116. In certain embodiments, the information handling system 100 is one of a plurality of information handling systems within a data center. In certain embodiments, the information handling system 100 comprises a server type information handling system. In certain embodiments, the server type information handling system is configured to be mounted within a server rack. In certain embodiments, the other subsystem 108 includes one or more power supplies for supplying power to the other components of the information handling system 100.

In certain embodiments, the information handling system 100 comprises a server type information handling system. In certain embodiments, the server type information handling system comprises a blade server type information handling system. As used herein, a blade server type information handling system broadly refers to an information handling system which is physically configured to be mounted within a server rack.

In certain embodiments, the storage system 150 comprises a storage system housing which includes a storage module thermal pad alignment system via which a thermal pad can be toollessly installed into a storage component of the storage system. In certain embodiments, the storage module thermal pad alignment system includes an alignment component. In certain embodiments, the alignment component is configured from a rigid material. In certain embodiments, the rigid material includes mylar. In certain embodiments, the one side of the thermal pad is adhered to the alignment component. In certain embodiments, the alignment component enhances the rigidness of the storage module thermal pad alignment system during operation. In certain embodiments, the thermal pad alignment system includes alignment indicia to indicate a position to which the thermal pad should be affixed. Such a storage module thermal pad alignment system enables a user to rework a storage component without the need for specific fixtures to facilitate the thermal pad rework process.

In certain embodiments, the alignment component includes additional alignment features which can be used with reworking a storage component. In certain embodiments, the additional alignment features facilitate positioning the thermal pad alignment system when reassembling the storage module thermal pad alignment system to a bottom component of a storage module.

In certain embodiments, the storage system comprises a boot optimized storage system. In certain embodiments, the boot optimized storage system comprises a redundant array of independent disks (RAID) solution optimized for booting an operating system of a server. In certain embodiments, the boot optimized storage system comprises a plurality of serial advanced technology advancement (SATA) solid state devices (SSDs), a host interface (such as a PCIe host interface), a device interface (such as a SATA device interface), or a combination thereof. In certain embodiments, the solid state devices are included within a storage card. In certain embodiments, the storage card corresponds to an M.2 type storage card. In certain embodiments, the storage card corresponds to a boot optimized storage system M.2 type storage card.

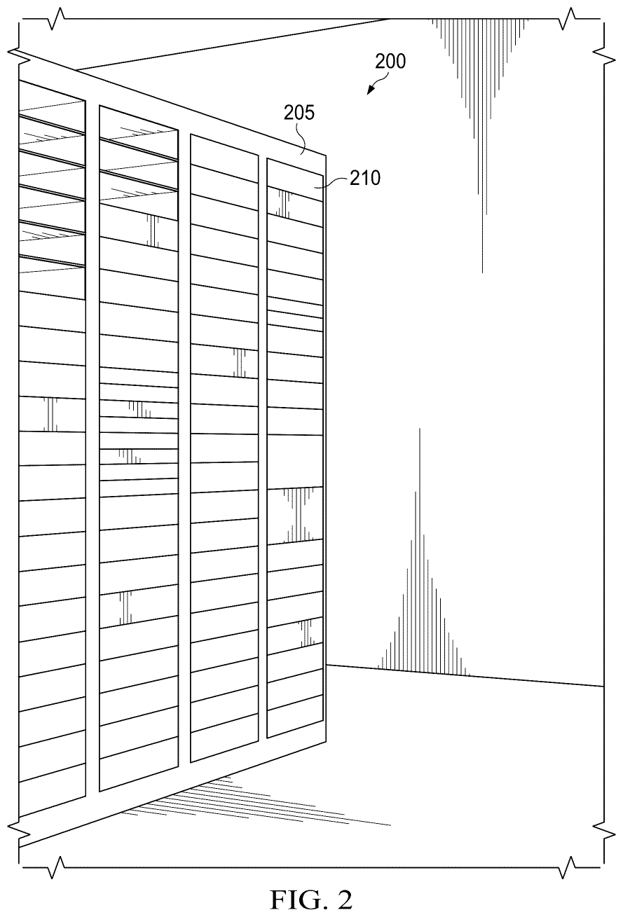

FIG. 2 shows a perspective view of a portion of an IT environment 200. The IT environment includes one or more racks 205 which include a plurality of information handling systems 100, often referred to as a server rack. In various embodiments, the IT environment 200 comprises a data center. As used herein, a data center refers to an IT environment which includes a plurality of networked information handling systems 100. In various embodiments, the information handling systems 100 of the data center include some or all of router type information handling systems, switch type information handling systems, firewall type information handling systems, storage system type information handling systems, server type information handling systems and application delivery controller type information handling systems. In certain environments, the information handling systems 100 are mounted within respective racks. As used herein, a rack refers to a physical structure that is designed to house the information handling systems 100, as well as the associated cabling and power provision for the information handling systems. In certain embodiments, a rack includes side panels to which the information handling systems are mounted. In certain embodiments, the rack includes a top panel and a bottom panel to which the side panels are attached. In certain embodiments, the side panels each include a front side panel and a rear side panel.

In certain embodiments, a plurality of racks is arranged continuous with each other to provide a rack system. An IT environment can include a plurality of rack systems arranged in rows with aisles via which IT service personnel can access information handling systems mounted in the racks. In certain embodiments, the aisles can include front aisles via which the front of the information handling systems may be accessed and hot aisles via which the infrastructure (e.g., data and power cabling) of the IT environment can be accessed.

Each respective rack includes a plurality of vertically arranged information handling systems 210. In certain embodiments, the information handling systems may conform to one of a plurality of standard server sizes. In certain embodiments, the plurality of server sizes conforms to particular rack unit sizes (i.e., rack units). As used herein, a rack unit broadly refers to a standardized server system height. As is known in the art, a server system height often conforms to one of a 1U rack unit, a 2U rack unit, and a 4U rack unit. In general, a 1U rack unit is substantially (i.e., +/−20%) 1.75″ high, a 2U rack unit is substantially (i.e., +/−20%) 3.5″ high, and a 4U rack height is substantially (i.e., +/−20%) 7.0″ high.

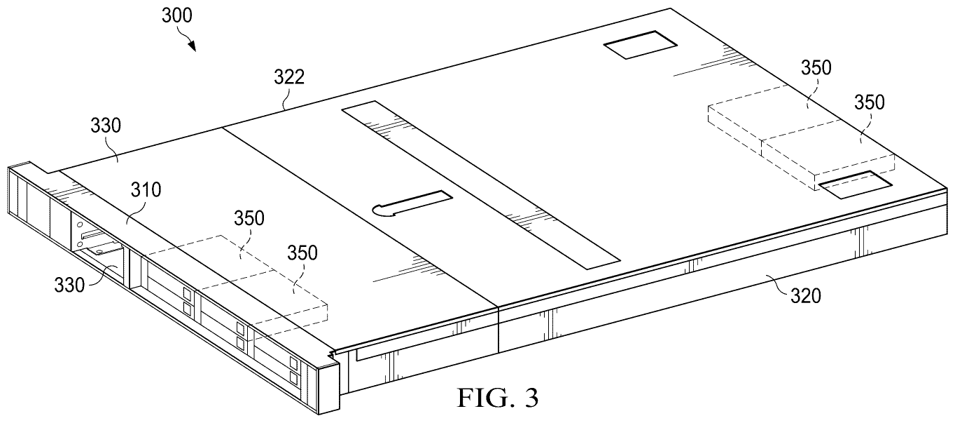

FIG. 3 shows a generalized perspective view of an example blade server type information handling system 300. In certain embodiments, the server type information handling system includes a front portion 310, which is accessible when the server type information handing system 300 is mounted on a server rack. In certain embodiments, the side portions 320, 322 mount to the rack via respective server mounting components. In certain embodiments, the side portions mount to the rack via respective mechanical guiding features which are mechanically coupled to respective server mounting components. In certain embodiments, the server type information handling system can slide out from the rack via the respective mechanical guiding features. In certain embodiments, internal components of the blade type information handling system 300 may be accessed by removing a top panel 330 of the blade type information handing system 300. In certain embodiments, the blade type information handing system 300 includes a bay 350 via which components may be mounted to the blade type information handling system. In certain embodiments, components mounted in one or more of the bays 310 include a storage system 350.

In certain embodiments, the storage system comprises a boot optimized storage system. In certain embodiments, the boot optimized storage system comprises a redundant array of independent disks (RAID) solution optimized for booting an operating system of a server. In certain embodiments, the boot optimized storage system comprises a plurality of serial advanced technology advancement (SATA) solid state devices (SSDs), a host interface (such as a PCIe host interface), a device interface (such as a SATA device interface), or a combination thereof. In certain embodiments, the solid state devices are included within a storage card. In certain embodiments, the storage card corresponds to an M.2 type storage card.

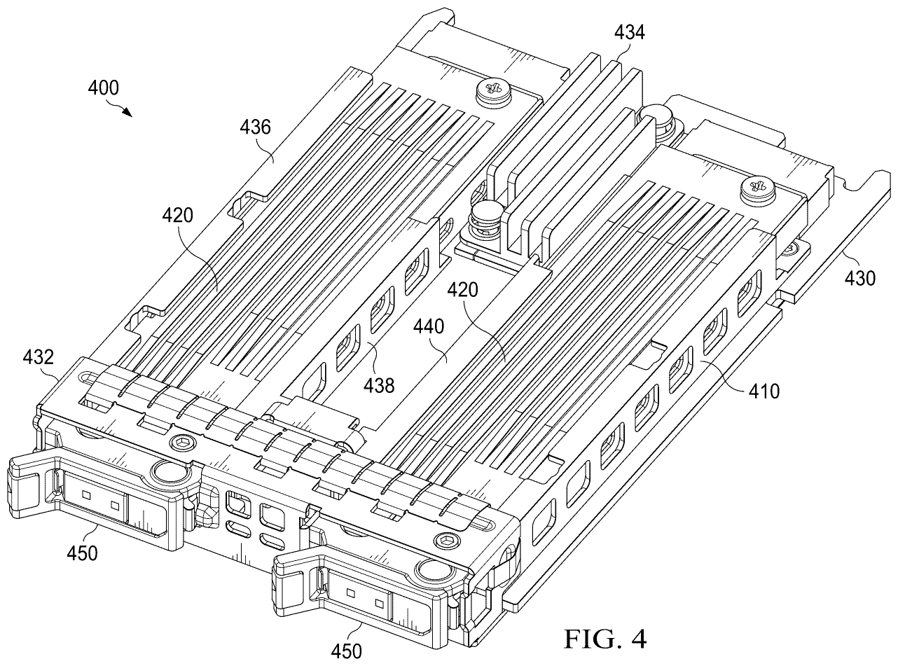

FIG. 4 shows a storage system 400 with a plurality of latching systems 405. In certain embodiments, the storage system 400 corresponds to storage system 150. In certain embodiments, each latching system 405 includes a latching mechanism and a latch engagement portion.

In certain embodiments, the storage system 400 corresponds to storage system 150. In certain embodiments, the storage module housing 410 includes a bottom wall 430, a front housing portion 432, an outside right wall 434, an outside left wall 436, an inside right wall 438, an inside left wall 440, or a combination thereof.

In certain embodiments, the housing portion 432 extends substantially perpendicularly (i.e., +/−20%) from the bottom wall 430. In certain embodiments, the front wall extends substantially perpendicularly (i.e., +/−20%) from the bottom wall 430. In certain embodiments, the outside right wall 434 extends substantially perpendicularly (i.e., +/−20%) from the bottom wall 430. In certain embodiments, the outside left wall 436 extends substantially perpendicularly (i.e., +/−20%) from the bottom wall 430. In certain embodiments, the right inside wall 438 extends substantially perpendicularly (i.e., +/−20%) from the bottom wall 430. In certain embodiments, the left inside wall 440 extends substantially perpendicularly (i.e., +/−20%) from the bottom wall 430. It will be appreciated that the orientations of the walls will be reversed when the storage system is installed at the rear of the information handling systems (e.g., the front housing portion 432 is effectively a rear housing portion).

In certain embodiments, the front housing portion 432 defines one or more apertures via which storage cartridge modules 420 may be installed in the storage module housing 410. In certain embodiments, pairs of left and right walls (e.g., a left outside wall and a right inside wall) include channels via which respective storage cartridges may be inserted and mounted to the storage module housing 410. In certain embodiments, the left and right walls include channels via which respective storage cartridges may be inserted and mounted to the storage module housing 410. In certain embodiments, the outside right wall 434 and the inside left wall 440 define channels via which a storage cartridge module 420 may be installed in the storage module housing 410. In certain embodiments, the outside left wall 436 and the inside right wall 438 define channels via which a storage cartridge module 420 may be installed in the storage module housing 410.

In certain embodiments, when the storage cartridge module 420 is configured in a hot swap storage media access configuration, each storage cartridge module 420 includes a respective latch 450 which allows a user to unlatch the storage cartridge module and remove the storage cartridge module from the storage system.

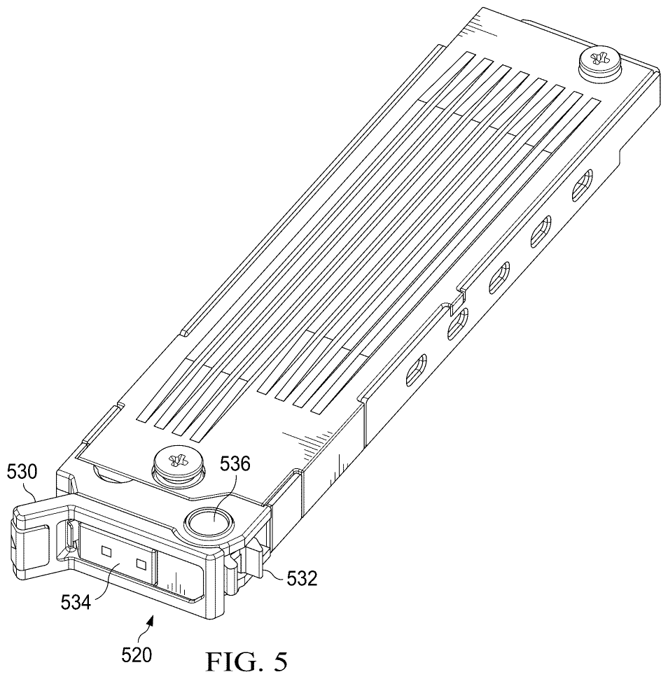

FIG. 5 shows a perspective view of a storage cartridge module 500 (also referred to as a storage module) of a storage system. In certain embodiments, the storage cartridge module 500 corresponds to storage cartridge module 420. In certain embodiments, the storage system corresponds to storage system 150.

In certain embodiments the storage cartridge module 500 includes a bottom component 510 and a top cover 512. In certain embodiments, the bottom component 510 and the top cover 512 are configured to receive a latch component 530. In certain embodiments, the bottom component 510 defines an attachment aperture, includes an attachment component, or a combination thereof. In certain embodiments, the attachment component includes a nut. In certain embodiments, the attachment aperture, the attachment component, or a combination thereof, are used to attach a latch component 530 to the storage cartridge module 500. In certain embodiments, the attachment component mates with a fastener to mount the top cover 512 to the bottom component 510.

In certain embodiments, a latch mechanism includes a latch hook portion 532. In certain embodiments, the latch 530 and the latch hook portion 532, or a combination thereof are included within a latch mechanism. In certain embodiments, the latch hook portion 532 is configured to interact with a latch engagement portion.

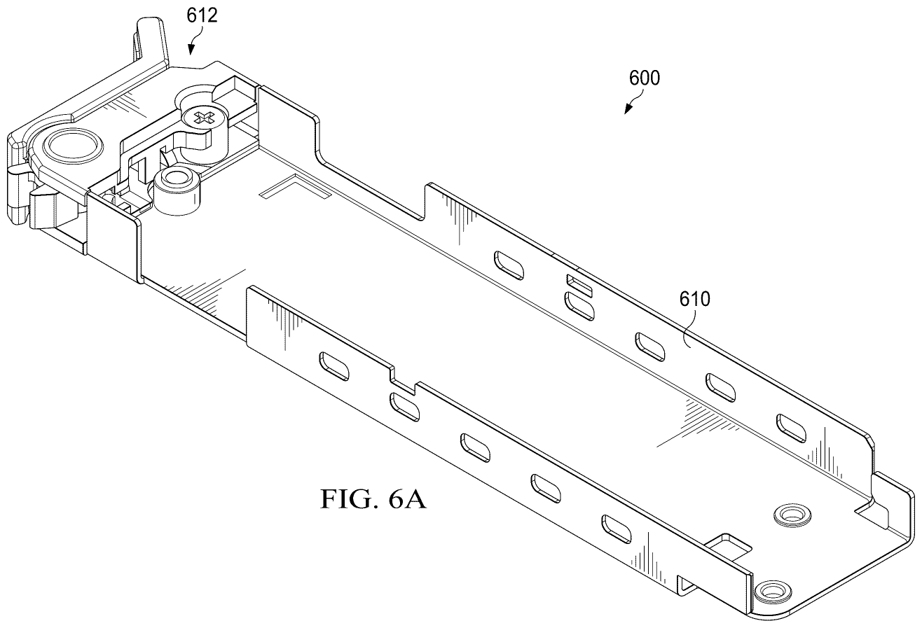

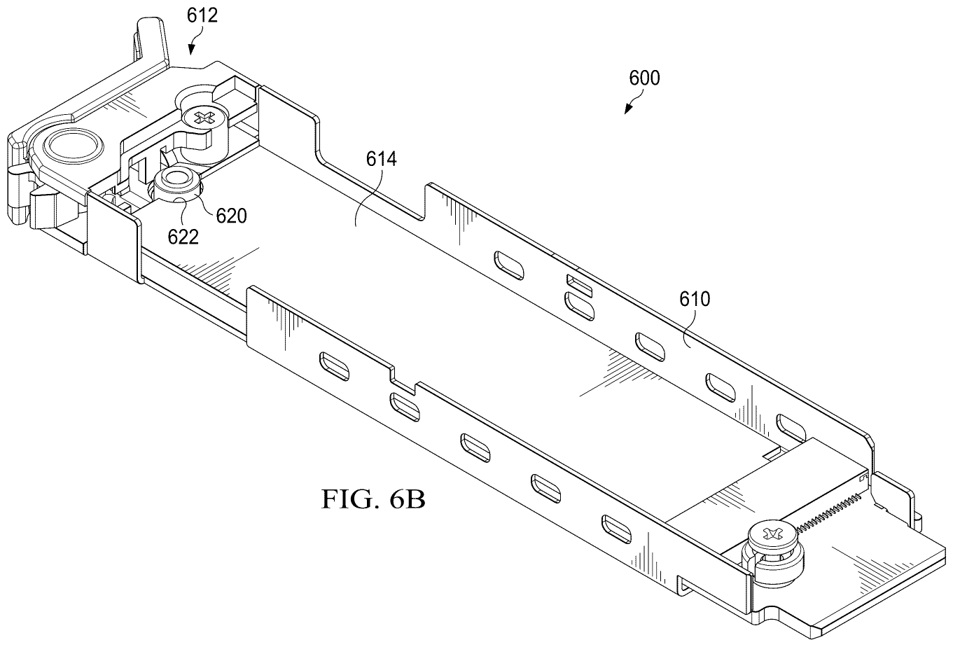

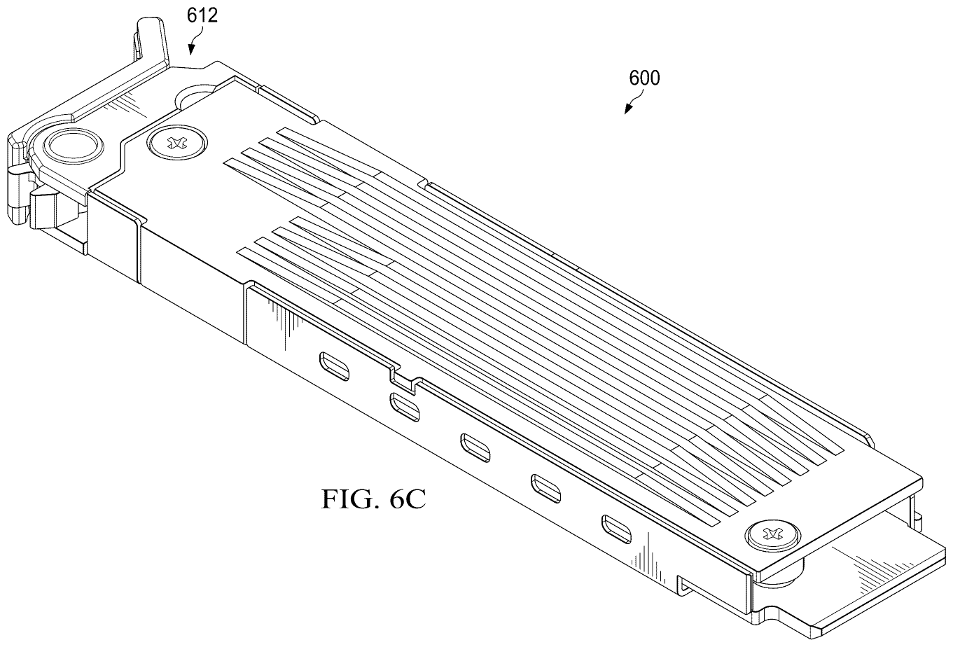

FIGS. 6A, 6B and 6C, generally referred to as FIG. 6, show a plurality of views of a storage component bottom system 600 of a storage module. More specifically, FIG. 6A shows a perspective view of a bottom system 600 without a card installed. FIG. 6C shows a perspective view of a bottom system 600 with a card installed. FIG. 6C shows a perspective view of a bottom system 600 along with an installed storage module thermal pad alignment system. In certain embodiments, the storage module corresponds to storage module 500.

In certain embodiments, the bottom system 600 includes a bottom component 610, a latch component 612, a card 614, a storage module thermal pad alignment system 616, a card connector 618, or a combination thereof. In certain embodiments, the bottom component 610 corresponds to bottom component 510.

In certain embodiments, the bottom component 610 includes a card alignment projection 620. In certain embodiments, the card alignment projection 620 is affixed to an inside wall of the bottom component 610. In certain embodiments, the card 614 includes a card alignment recess 622. In certain embodiments, the card alignment recess 622 mates with the card alignment projection 620 when the card is mounted to the card connector 618. In certain embodiments, a wall of the bottom component 610 defines a bottom component mating recess 626. In certain embodiments, one or both walls of the bottom component define bottom component mating slots 628.

In certain embodiments, the storage module thermal pad alignment system 616 enables a thermal pad to be toollessly installed into a storage component of the storage system. In certain embodiments, the storage module thermal pad alignment system 616 includes an alignment component. In certain embodiments, the alignment component is configured from a rigid material. In certain embodiments, the rigid material includes mylar. In certain embodiments, the one side of the thermal pad is adhered to the alignment component. In certain embodiments, the alignment component enhances the rigidness of the storage module thermal pad alignment system during operation. In certain embodiments, the thermal pad alignment system includes alignment indicia to indicate a position to which the thermal pad should be affixed. Such a storage module thermal pad alignment system enables a user to rework a storage component without the need for specific fixtures to facilitate the thermal pad rework process.

In certain embodiments, the alignment component includes additional alignment features which can be used with reworking a storage component. In certain embodiments, the additional alignment features facilitate positioning the thermal pad alignment system when reassembling the storage module thermal pad alignment system to a bottom component of a storage module.

In certain embodiments, the storage system comprises a boot optimized storage system. In certain embodiments, the boot optimized storage system comprises a redundant array of independent disks (RAID) solution optimized for booting an operating system of a server. In certain embodiments, the boot optimized storage system comprises a plurality of serial advanced technology advancement (SATA) solid state devices (SSDs), a host interface (such as a PCIe host interface), a device interface (such as a SATA device interface), or a combination thereof. In certain embodiments, the solid state devices are included within a storage card. In certain embodiments, the storage card corresponds to an M.2 type storage card. In certain embodiments, the storage card corresponds to a boot optimized storage system M.2 type storage card.

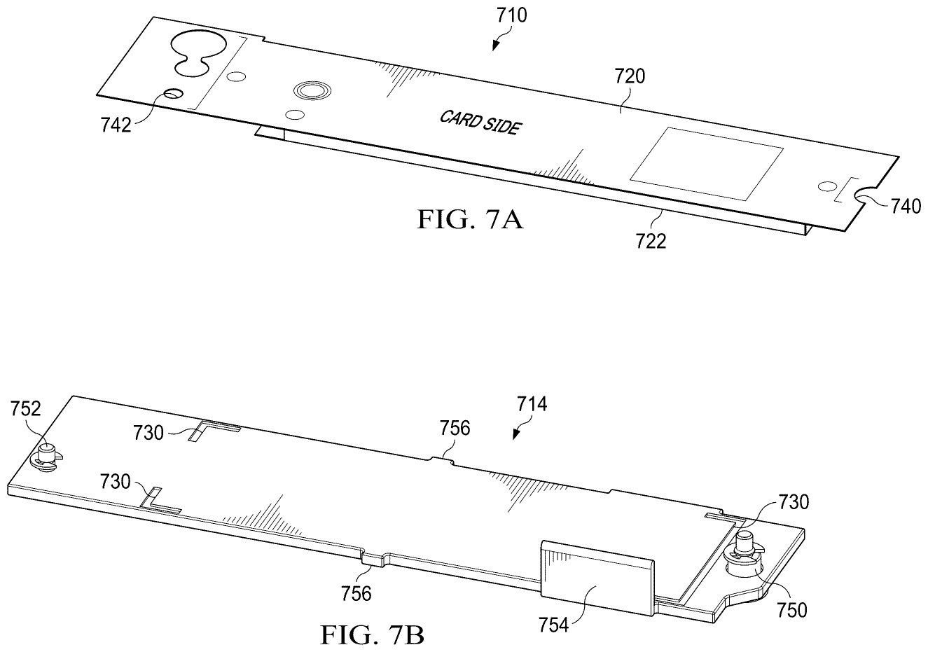

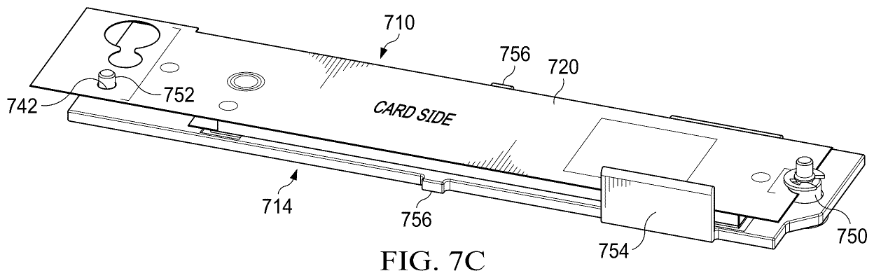

FIGS. 7A, 7B and 7C, generally referred to as FIG. 7, show a storage module thermal pad alignment system 700. More specifically, FIG. 7A shows a bottom perspective view of an alignment component of a storage module thermal pad alignment system, FIG. 7B shows a top perspective view of a top panel component of a storage module thermal pad alignment system 700. FIG. 7C shows a bottom perspective view of storage module thermal pad alignment system 700. In certain embodiments, the storage module thermal pad alignment system 700 corresponds to storage module thermal pad alignment system 616.

In certain embodiments, the storage module thermal pad alignment system 700 includes an alignment component 710, a top panel component 714, or a combination thereof. In certain embodiments, the alignment component 710 includes an alignment panel 720, a thermal pad 722, or a combination thereof. In certain embodiments, the alignment panel 720 is preassembled with the thermal pad component 722. In certain embodiments, the alignment panel 720 and the thermal pad component 722 are configured as a single part. As used herein, a single part broadly refers to a device which is available from a supplier under a single stockkeeping unit (SKU). In certain embodiments, the alignment panel 720 and the thermal pad component 722 are provided by a supplier to an end user for the end user to rework a storage component. In certain embodiments, the thermal pad component 722 is affixed to a wall of the alignment panel 720 so as to be easily installed to a storage module when the storage module is reworked. In certain embodiments, the thermal pad component is affixed to the wall of the alignment panel in a preconfigured position so as to easily mate with a top panel component of the storage module thermal pad alignment system 700.

In certain embodiments, the storage module thermal pad alignment system 700 enables a thermal pad to be toollessly installed into a storage component of the storage system. In certain embodiments, the alignment panel 720 is configured from a rigid material. In certain embodiments, the rigid material includes mylar. In certain embodiments, one side of the thermal pad component 722 is adhered to the alignment panel 720. In certain embodiments, the alignment panel 720 enhances the rigidness of the storage module thermal pad alignment system 700 during operation. In certain embodiments, the alignment panel 720 includes an outside wall, an inside wall, or a combination thereof. In certain embodiments, the thermal cap component 722 is affixed to the inside wall of the alignment panel 720. In certain embodiments, the inside wall of the alignment panel 720 is configured to be mounted opposite to an inside wall of a top panel component.

In certain embodiments, the top panel component 714 includes alignment indicia 730 to indicate a position to which the thermal pad component 722 of the alignment component 710 should be affixed to the top panel component 714. In certain embodiments, the alignment indicia 730 include a first L-shaped projection, a second L-shaped projection, a substantially U-shaped projection, or a combination thereof. In certain embodiments, the first L-shaped projection is positioned to align a first corner of the thermal pad component 722. In certain embodiments, the second L-shaped projection is positioned to align a second corner of the thermal pad component 722. In certain embodiments, the substantially U-shaped projection is configured to align a wall of the thermal pad component 722. In certain embodiments, the wall of the thermal pad component 722 is opposite the first corner, the second corner, or a combination thereof. Such a storage module alignment indicia enables a user to rework a storage component without the need for specific fixtures to facilitate the thermal pad rework process. In certain embodiments, the alignment indicia 730 allows the thermal pad component 722 to be properly positioned on the top panel component 714.

In certain embodiments, the alignment component 710 includes additional alignment features which can be used when reworking a storage component. In certain embodiments, the additional alignment features include an alignment recess 740, an alignment aperture 742, or a combination thereof. In certain embodiments, the alignment recess 740 mates with a projection 750 positioned on the top panel component 714. In certain embodiments, the alignment aperture mates with an alignment component attachment projection 752 positioned on the top panel component 714. In certain embodiments, the additional alignment features facilitate positioning the alignment component 710 to the top panel component 714. In certain embodiments, the projection 750, the alignment component attachment projection 752, or a combination thereof, are positioned on an inside wall of the top panel component 714.

In certain embodiments, the additional alignment features further facilitate positioning the thermal pad alignment system 700 when reassembling the storage module thermal pad alignment system to a bottom component of a storage module. For example, the projection 750 is configured to mate with a card alignment projection (such as card alignment projection 620 of a bottom component. In certain embodiments, the top panel component 714 may be configured with an alignment wall 754. In certain embodiments, the alignment wall 754 is configured to mate with a bottom component mating recess (such as bottom component mating recess 626) of a bottom component. In certain embodiments, the top panel component 714 may be configured with one or more alignment projections 756. In certain embodiments, each alignment projection 756 is configured to mate with a bottom component mating slot (such as bottom component mating slot 628) of a bottom component.

The present invention is well adapted to attain the advantages mentioned as well as others inherent therein. While the present invention has been depicted, described, and is defined by reference to particular embodiments of the invention, such references do not imply a limitation on the invention, and no such limitation is to be inferred. The invention is capable of considerable modification, alteration, and equivalents in form and function, as will occur to those ordinarily skilled in the pertinent arts. The depicted and described embodiments are examples only, and are not exhaustive of the scope of the invention.

Consequently, the invention is intended to be limited only by the spirit and scope of the appended claims, giving full cognizance to equivalents in all respects.

What is claimed is:

1. An alignment component of a storage module thermal pad alignment system for use with a storage system for an information handling system, comprising:
an alignment panel, the alignment panel including an outside wall and an inside wall; and,
a thermal pad, the thermal pad being affixed to the inside wall of the alignment panel in a preconfigured position, the alignment panel and the thermal pad being configured as a single part.

2. The alignment component of claim 1, wherein:
the alignment component is configured to enable a thermal pad to be toollessly installed into a storage component of a storage module.

3. The alignment component of claim 1, wherein:
the alignment panel is configured to be attached to a top panel component of a storage module thermal pad alignment system.

4. The alignment component of claim 3, wherein:
the alignment panel includes an alignment feature, the alignment feature aligning the alignment panel with the top panel component when the alignment panel is attached to the top panel component.

5. The alignment component of claim 4, wherein:
the alignment feature includes at least one of an alignment recess and an alignment aperture, the alignment recess being configured to mate with a projection positioned on the top panel component, the alignment aperture being configured to mate with an alignment component attachment projection position ed on the top panel component.

6. The alignment component of claim 3, wherein:
the top panel component includes alignment indicia, indicating a position to which the thermal pad should be affixed to the top panel component.

7. A bottom system of a storage system comprising:
a bottom component; and,
a storage module thermal pad alignment system for attaching to the bottom component, the storage module thermal pad alignment system comprising an alignment component, the alignment component comprising
an alignment panel, the alignment panel including an outside wall and an inside wall; and,
a thermal pad, the thermal pad being affixed to the inside wall of the alignment panel in a preconfigured position, the alignment panel and the thermal pad being configured as a single part.

8. The bottom system of claim 7, wherein:
the alignment component is configured to enable a thermal pad to be toollessly installed into a storage component of a storage module.

9. The bottom system of claim 7, wherein:
the storage module thermal pad alignment system further comprises a top panel component; and,
the alignment panel is configured to be attached to the top panel component of a storage module thermal pad alignment system.

10. The bottom system of claim 9, wherein:
the alignment panel includes an alignment feature, the alignment feature aligning the alignment panel with the top panel component when the alignment panel is attached to the top panel component.

11. The bottom system of claim 10, wherein:
the alignment feature includes at least one of an alignment recess and an alignment aperture, the alignment recess being configured to mate with a projection positioned on the top panel component, the alignment aperture being configured to mate with an alignment component attachment projection position ed on the top panel component.

12. The bottom system of claim 10, wherein:
the top panel component includes alignment indicia, indicating a position to which the thermal pad should be affixed to the top panel component.

13. A system comprising:
a chassis;
a processor contained within the chassis;
a data bus coupled to the processor; and,
a storage system comprising a bottom system, the bottom system comprising
a bottom component; and,
a storage module thermal pad alignment system for attaching to the bottom component, the storage module thermal pad alignment system comprising an alignment component, the alignment component comprising
an alignment panel, the alignment panel including an outside wall and an inside wall; and,
a thermal pad, the thermal pad being affixed to the inside wall of the alignment panel in a preconfigured position, the alignment panel and the thermal pad being configured as a single part.

14. The system of claim 13, wherein:
the alignment component is configured to enable a thermal pad to be toollessly installed into a storage component of a storage module.

15. The system of claim 13, wherein:
the storage module thermal pad alignment system further comprises a top panel component; and,
the alignment panel is configured to be attached to the top panel component of a storage module thermal pad alignment system.

16. The system of claim 15, wherein:
the alignment panel includes an alignment feature, the alignment feature aligning the alignment panel with the top panel component when the alignment panel is attached to the top panel component.

17. The system of claim 16, wherein:
the alignment feature includes at least one of an alignment recess and an alignment aperture, the alignment recess being configured to mate with a projection positioned on the top panel component, the alignment aperture being configured to mate with an alignment component attachment projection position ed on the top panel component.

18. The system of claim 15, wherein:
the top panel component includes alignment indicia, indicating a position to which the thermal pad should be affixed to the top panel component.
